(19) United States
(12) Patent Application Publication
(10) Pub. No.: US 2026/0141937 A1
(43) Pub. Date: May 21, 2026

(54) MEMORY DEVICE AND FABRICATING METHOD THEREOF

(71) Applicant: TAIWAN SEMICONDUCTOR MANUFACTURING COMPANY, LTD., Hsinchu (TW)

(72) Inventors: Dian-Sheng YU, Hsinchu City (TW); Chia He CHUNG, Hsinchu City (TW); Chih-Yung LIN, Hsinchu County (TW); Kuo-Hua PAN, Hsinchu City (TW)

(73) Assignee: TAIWAN SEMICONDUCTOR MANUFACTURING COMPANY, LTD., Hsinchu (TW)

(21) Appl. No.: 18/955,251

(22) Filed: Nov. 21, 2024

(51) Int. Cl. G11C 8/08; G11C 5/06

(52) U.S. Cl. CPC G11C 8/08; G11C 5/063

(57) ABSTRACT

A device includes a first memory cell, a second memory cell, a first conductive feature and a second conductive feature. The first memory cell is configured to receive a first word line signal. The second memory cell is adjacent with the first memory cell, and configured to receive a second word line signal. The first conductive feature crosses over each of the first memory cell and the second memory cell, and is configured to transmit the first word line signal. The second conductive feature crosses over each of the first memory cell and the second memory cell, is overlapped with the first conductive feature, and is configured to transmit the second word line signal.

### BACKGROUND

As technology scales, power, performance and area (PPA) become more challenging to achieve the desired power, performance, and area targets. Especially in back-end of line (BEOL) metal line resistivity increase to limit memory devices word-lines access time and bit-lines high speed applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory system illustrated in accordance with some embodiments of the present disclosure.

FIG. 2 is a circuit diagram of further details of part of the memory device shown in FIG. 1, illustrated in accordance with some embodiments of the present disclosure.

FIG. 3A is a schematic diagram of a memory device corresponding to the memory device shown in FIG. 2, illustrated in accordance with some embodiments of the present disclosure.

FIG. 3B is a schematic diagram of cross-sectional view along a line of the memory device shown in FIG. 3A, illustrated in accordance with some embodiments of the present disclosure.

FIG. 3C is a schematic diagram of cross-sectional view along a line of the memory device shown in FIG. 3A, illustrated in accordance with some embodiments of the present disclosure.

FIG. 3D is a schematic diagram of further details of the memory device shown in FIG. 3A, illustrated in accordance with some embodiments of the present disclosure.

FIG. 3E is a schematic diagram of further details of the memory device shown in FIG. 3D, illustrated in accordance with some embodiments of the present disclosure.

FIG. 3F is a schematic diagram of further details of the memory device shown in FIG. 3E, illustrated in accordance with some embodiments of the present disclosure.

FIG. 3G is a schematic diagram of further details of the memory device shown in FIG. 3F, illustrated in accordance with some embodiments of the present disclosure.

FIG. 3H is a schematic diagram of further details of the memory device shown in FIG. 3G, illustrated in accordance with some embodiments of the present disclosure.

FIG. 4 is a flowchart diagram of a method for fabricating the memory devices described above, illustrated in accordance with some embodiments of the present disclosure.

FIG. 5 is a schematic view of a system for designing and manufacturing at least one of the semiconductor devices described above, illustrated in accordance with some embodiments of the present disclosure.

FIG. 6 is a block diagram of an integrated circuit (IC)/semiconductor device manufacturing system, and an IC manufacturing flow associated therewith, illustrated in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

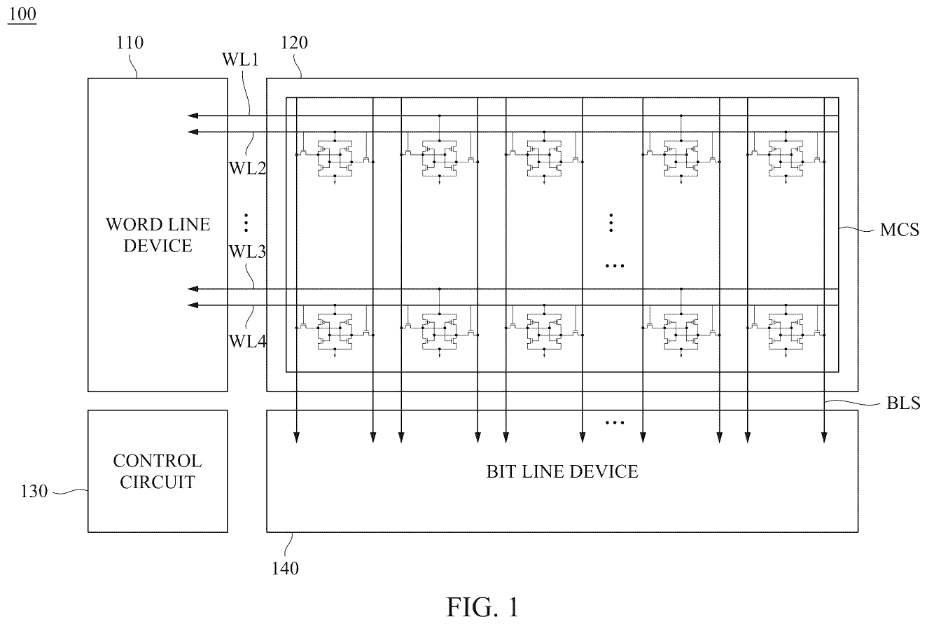

FIG. 1 is a schematic diagram of a memory system 100 illustrated in accordance with some embodiments of the present disclosure. As illustratively shown in FIG. 1, the memory system 100 includes a word line device 110, a memory device 120, a control circuit 130 and a bit line device 140. The control circuit 130 is configured to control the word line device 110 and the bit line device 140. The word line device 110 is configured to provide word line signals to the memory device 120. The bit line device 140 is configured to receive bit line signals from the memory device 120.

In some embodiments, the word line device 110 is implemented by a row decoder and a word line driver. The bit line device 140 is implemented by a column multiplexer for bit line connection. The memory device 120 is implemented by a static random-access memory (SRAM) array. In some embodiments, the word line device 110, memory device 120, the control circuit 130 and the bit line device 140 are referred to as semiconductor devices.

As illustratively shown in FIG. 1, the memory device 120 includes multiple memory cells MCS, multiple bit lines BLS and multiple word lines, such as word lines WL1-WL4. The memory cells MCS are coupled to the bit lines BLS. Some of the memory cells MCS are coupled to corresponding ones of the word lines WL1-WL4.

In some embodiments, the word lines are disposed in different layers. For example, the word lines WL1 and WL3 are disposed in a metal-five (M5) layer, and the word lines WL2 and WL4 are disposed in a metal-three (M3) layer which is lower than the M5 layer. In some embodiments, the bit lines BLS are disposed in a metal-two (M2) which is lower than the M3 layer.

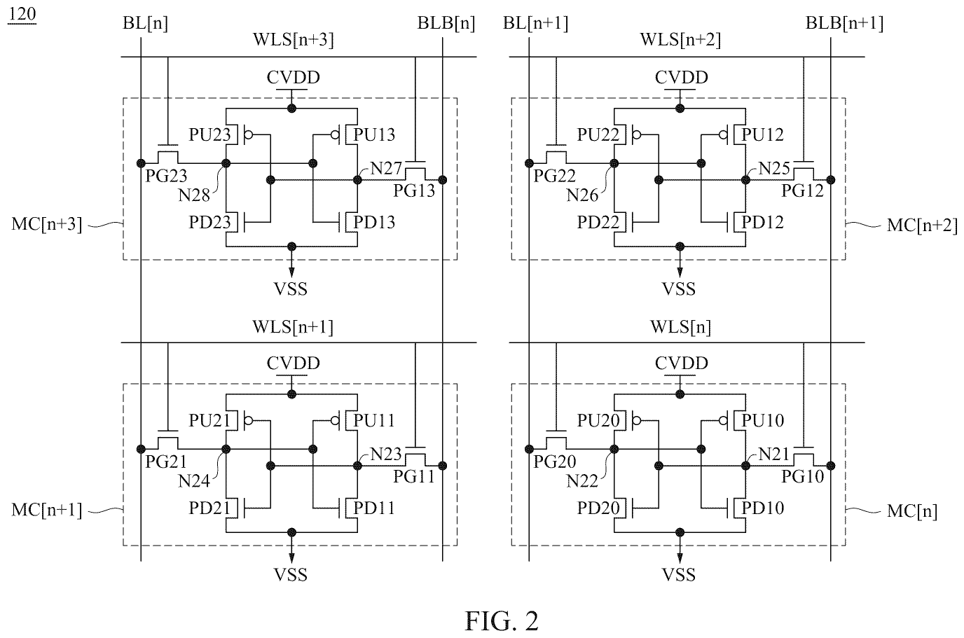

FIG. 2 is a circuit diagram of further details of part of the memory device 120 shown in FIG. 1, illustrated in accordance with some embodiments of the present disclosure. As illustratively shown in FIG. 2, the memory device 120 includes memory cells MC[n]-MC[n+3], in which n is a non-negative integer.

The memory cells MC[n]-MC[n+3] are configured to receive word line signals WLS[n]-WLS[n+3], respectively. Each of the memory cells MC[n] and MC[n+2] is configured to receive bit line signals BL[n+1] and BLB[n+1]. Each of the memory cells MC[n+1] and MC[n+3] is configured to receive bit line signals BL[n] and BLB[n]. In some embodiments, the bit line signals BL[n+1] and BLB[n+1] are complementary with each other, and the bit line signals BL[n] and BLB[n] are complementary with each other.

As illustratively shown in FIG. 2, the memory cell MC[n] includes switches PG10, PG20, PU10, PU20, PD10 and PD20. Each of control terminals of the switches PG10 and PG20 is configured to receive the word line signal WLS[n]. A terminal of the switch PG10 is configured to receive the bit line signal BL[n+1], and another terminal of the switch PG10 is coupled to a node N21. A terminal of the switch PG20 is configured to receive the bit line signal BLB[n+1], and another terminal of the switch PG20 is coupled to a node N22. Each of control terminals of the switches PU10 and PD10 is coupled to the node N22. A terminal of the switch PU10 is configured to receive a reference voltage signal CVDD, another terminal of the switch PU10 is coupled to the node N21. A terminal of the switch PD10 is configured to receive a reference voltage signal VSS, another terminal of the switch PU10 is coupled to the node N21. Each of control terminals of the switches PU20 and PD20 is coupled to the node N21. A terminal of the switch PU20 is configured to receive the reference voltage signal CVDD, another terminal of the switch PU20 is coupled to the node N22. A terminal of the switch PD20 is configured to receive the reference voltage signal VSS, another terminal of the switch PU20 is coupled to the node N22.

Similarly, the memory cell MC[n+1] includes switches PG11, PG21, PU11, PU21, PD11 and PD21. Each of control terminals of the switches PG11 and PG21 is configured to receive the word line signal WLS[n+1]. A terminal of the switch PG11 is configured to receive the bit line signal BL[n], and another terminal of the switch PG11 is coupled to a node N23. A terminal of the switch PG21 is configured to receive the bit line signal BLB[n], and another terminal of the switch PG21 is coupled to a node N24. Each of control terminals of the switches PU11 and PD11 is coupled to the node N24. A terminal of the switch PU11 is configured to receive the reference voltage signal CVDD, another terminal of the switch PU11 is coupled to the node N23. A terminal of the switch PD11 is configured to receive the reference voltage signal VSS, another terminal of the switch PU11 is coupled to the node N23. Each of control terminals of the switches PU21 and PD21 is coupled to the node N23. A terminal of the switch PU21 is configured to receive the reference voltage signal CVDD, another terminal of the switch PU21 is coupled to the node N24. A terminal of the switch PD21 is configured to receive the reference voltage signal VSS, another terminal of the switch PU21 is coupled to the node N24.

Similarly, the memory cell MC[n+2] includes switches PG12, PG22, PU12, PU22, PD12 and PD22. Each of control terminals of the switches PG12 and PG22 is configured to receive the word line signal WLS[n+2]. A terminal of the switch PG12 is configured to receive the bit line signal BL[n+1], and another terminal of the switch PG12 is coupled to a node N25. A terminal of the switch PG22 is configured to receive the bit line signal BLB[n+1], and another terminal of the switch PG22 is coupled to a node N26. Each of control terminals of the switches PU12 and PD12 is coupled to the node N26. A terminal of the switch PU12 is configured to receive the reference voltage signal CVDD, another terminal of the switch PU12 is coupled to the node N25. A terminal of the switch PD12 is configured to receive the reference voltage signal VSS, another terminal of the switch PU12 is coupled to the node N25. Each of control terminals of the switches PU22 and PD22 is coupled to the node N25. A terminal of the switch PU22 is configured to receive the reference voltage signal CVDD, another terminal of the switch PU22 is coupled to the node N26. A terminal of the switch PD22 is configured to receive the reference voltage signal VSS, another terminal of the switch PU22 is coupled to the node N26.

Similarly, the memory cell MC[n+3] includes switches PG13, PG23, PU13, PU23, PD13 and PD23. Each of control terminals of the switches PG13 and PG23 is configured to receive the word line signal WLS[n+3]. A terminal of the switch PG13 is configured to receive the bit line signal BL[n], and another terminal of the switch PG13 is coupled to a node N27. A terminal of the switch PG23 is configured to receive the bit line signal BLB[n], and another terminal of the switch PG23 is coupled to a node N28. Each of control terminals of the switches PU13 and PD13 is coupled to the node N28. A terminal of the switch PU13 is configured to receive the reference voltage signal CVDD, another terminal of the switch PU13 is coupled to the node N21. A terminal of the switch PD13 is configured to receive a reference voltage signal VSS, another terminal of the switch PU13 is coupled to the node N27. Each of control terminals of the switches PU23 and PD23 is coupled to the node N27. A terminal of the switch PU23 is configured to receive the reference voltage signal CVDD, another terminal of the switch PU23 is coupled to the node N28. A terminal of the switch PD23 is configured to receive the reference voltage signal VSS, another terminal of the switch PU23 is coupled to the node N28.

In some embodiments, the switches PU10-PU13 and PU20-PU23 are implemented by first type of transistors, such as P-type transistors, and the switches PD10-PD13, PD20-PD23, PG10-PG13 and PG20-PG23 are implemented by second type of transistors, such as N-type transistors. The bit line signal BL[n] is complementary with the bit line signal BLB[n]. The bit line signal BL[n+1] is complementary with the bit line signal BLB[n+1]. The reference voltage level CVDD has a power voltage level. The reference voltage level VSS has a ground voltage level which is lower than the power voltage level.

In various embodiments, the word line signals WLS[n]-WLS[n+3] can be different from or same as one another. For example, in some embodiments, the word line signals WLS[n]-WLS[n+3] are same as each other. In some embodiments, the word line signals WLS[n]-WLS[n+3] are different from each other. In some embodiments, the word line signals WLS[n] and WLS[n+1] are the same, the word line signals WLS[n+2] and WLS[n+3] are the same, and the word line signals WLS[n] and WLS[n+2] are different from each other.

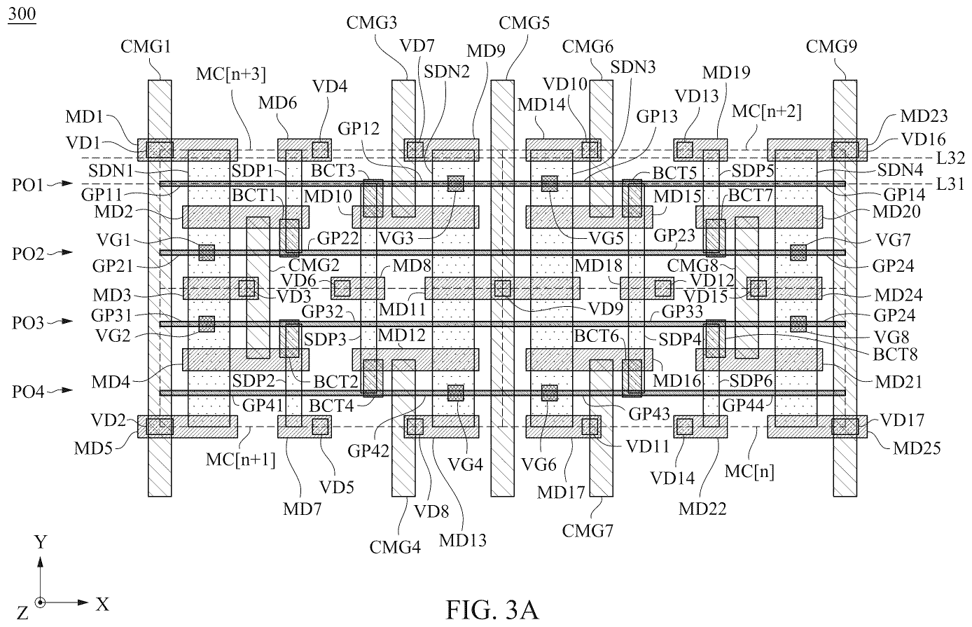

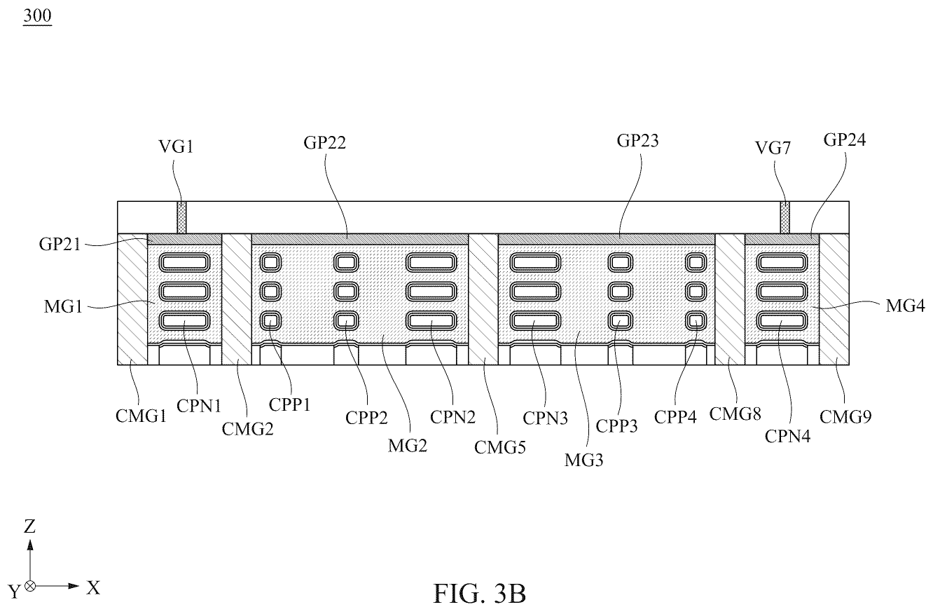

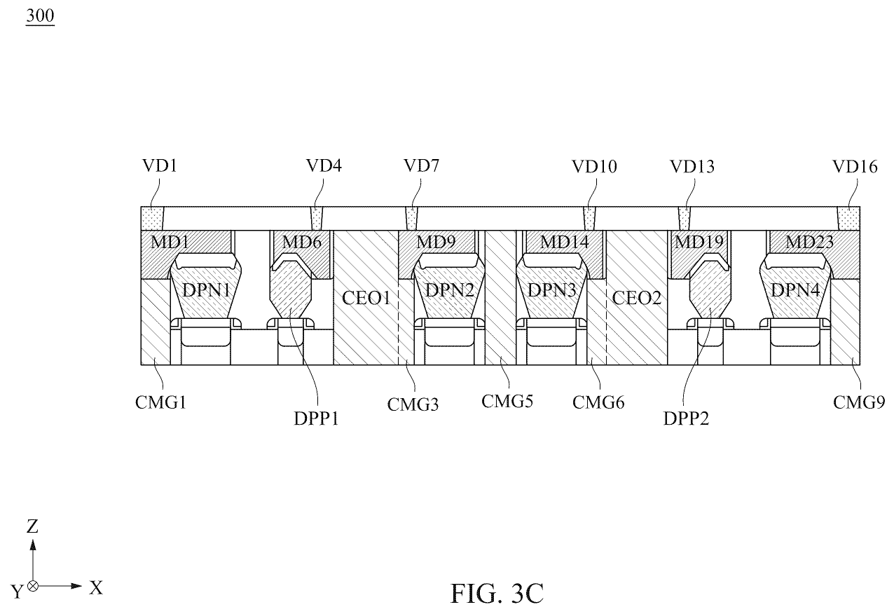

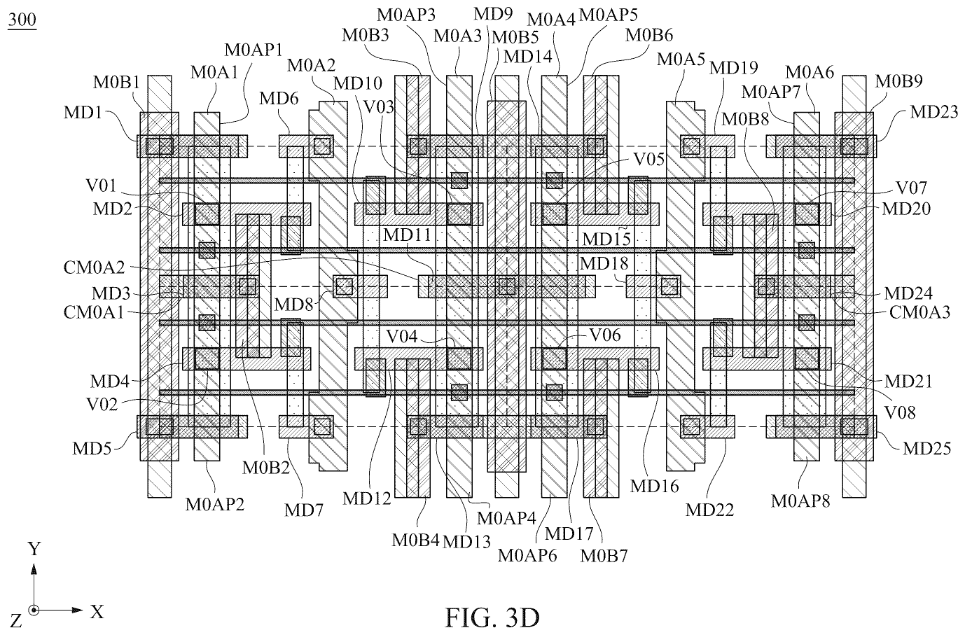

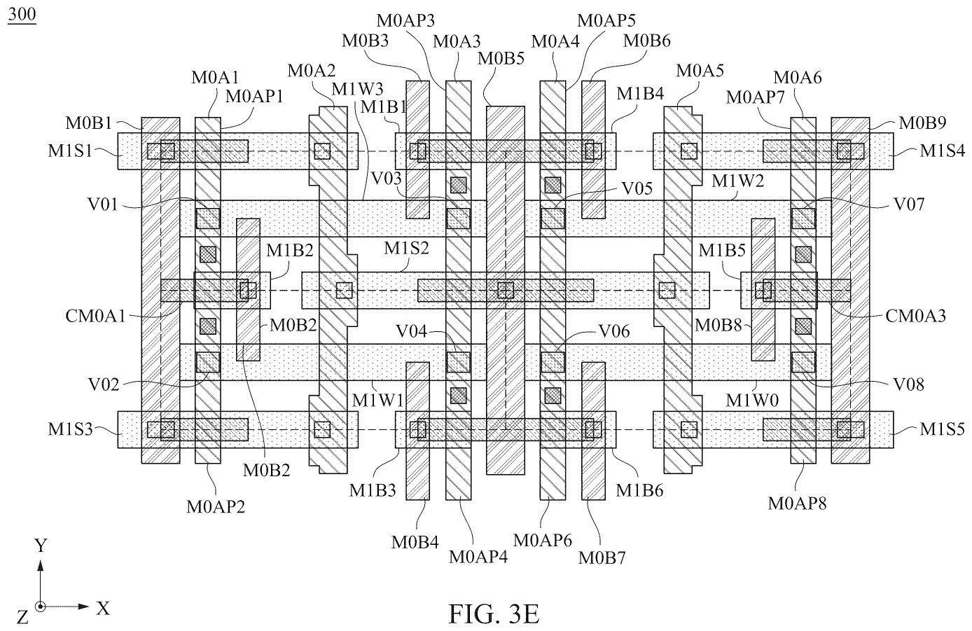

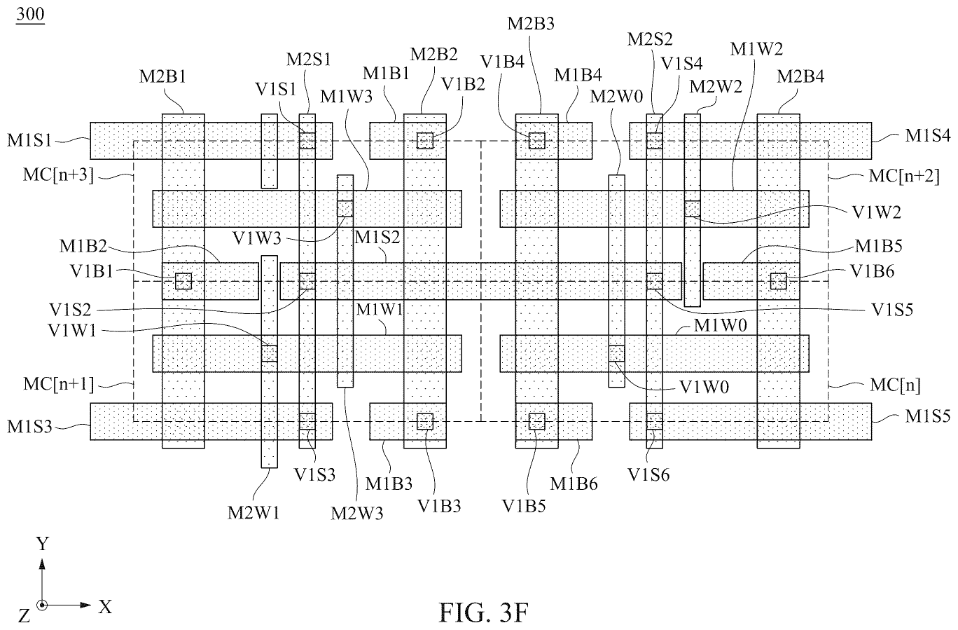

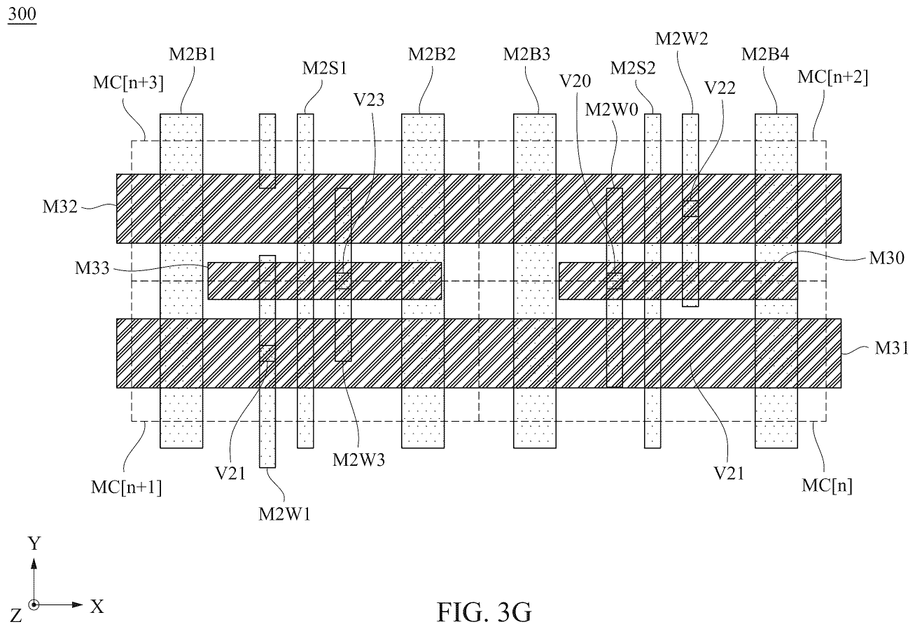

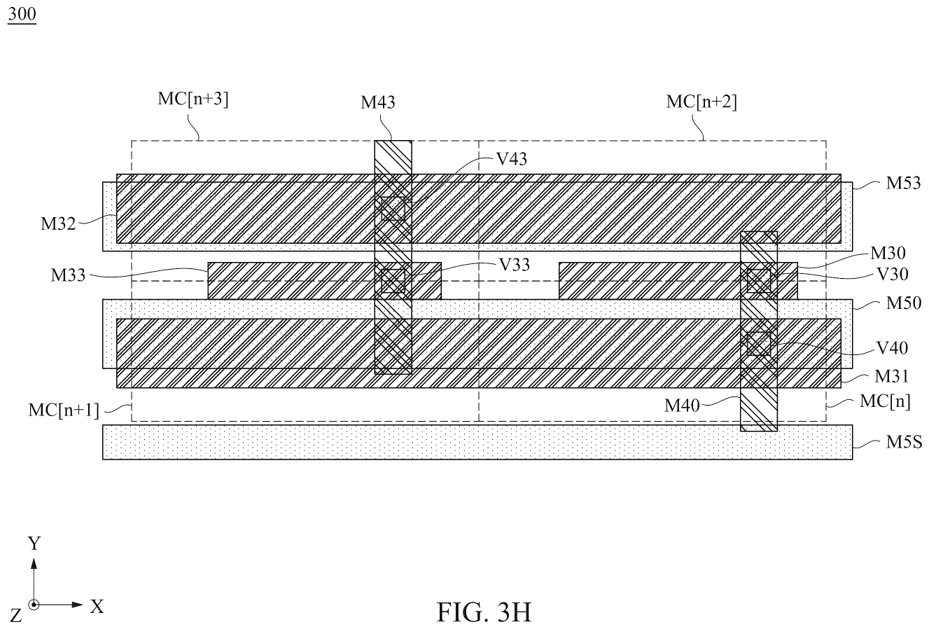

FIG. 3A is a schematic diagram of a memory device 300 corresponding to the memory device 120 shown in FIG. 2, illustrated in accordance with some embodiments of the present disclosure. As illustratively shown in FIG. 3A, the memory device 300 includes source/drain structures SDN1-SDN4, SDP1-SDP6, gate structures PO1-PO4, cut regions CMG1-CMG9, conductive features MD1-MD25, BCT1-BCT8, via structures VG1-VG8, VD1-VD17.

In some embodiments, the source/drain structures SDN1-SDN4 are implemented by first type of material, such as N-type material, and the source/drain structures SDP1-SDP6 are implemented by second type of material, such as P-type material. In some embodiments, the gate structures PO1-PO4 are implemented by poly-silicon. In some embodiments, the conductive features MD1-MD25, BCT1-BCT8 and the via structures VG1-VG8, VD1-VD17 are implemented by conductive material, such as metal. In some embodiments, the conductive features are implemented by conductive segments, such as metal lines.

Each of the source/drain structures SDN1-SDN4, SDP1-SDP6, the cut regions CMG1-CMG9, the conductive features BCT1-BCT8 is elongated along a Y direction. Each of the conductive features MD1-MD25 and the gate structures PO1-PO4 is elongated along a X direction. In FIG. 3A, a Z direction points out from the paper. In some embodiments, the X direction, the Y direction and the Z direction are perpendicular with each other.

Along the X direction, the source/drain structures SDN1, SDP1, SDP3, SDN2, SDN3, SDP4, SDP5 and SDN4 are arranged in order and separated from each other. The source/drain structures SDP2 and SDP6 are respectively aligned with the source/drain structures SDP1 and SDP5 along the Y direction. Along the Y direction, the gate structures PO1-PO4 are arranged in order and separated from each other.

Along the X direction, the cut regions CMG1, CMG2, CMG3, CMG5, CMG6, CMG8 and CMG9 are arranged in order and separated from each other. The cut regions CMG4 and CMG7 are respectively aligned with the cut regions CMG3 and CMG6 along the Y direction.

Each of cut regions CMG1, CMG5 and CMG9 are configured to cut the gate structures PO1-PO4. Each of cut regions CMG2 and CMG8 are configured to cut the gate structures PO2-PO3. Each of cut regions CMG3 and CMG6 are configured to cut the gate structure PO1. Each of cut regions CMG4 and CMG7 are configured to cut the gate structure PO4. Accordingly, the gate structure PO1 is separated into gate portions GP11-GP14. The gate structure PO2 is separated into gate portions GP21-GP24. The gate structure PO3 is separated into gate portions GP31-GP34. The gate structure PO4 is separated into gate portions GP41-GP44.

In some embodiments, after the gate structures PO1-PO4 are cut by the cut regions CMG1-CMG9, nitride material (such as silicon nitride) is filled into the cut regions CMG1-CMG9 to form nitride structures. Sizes of the nitride structures are approximately equal to sizes of the cut regions CMG1-CMG9, respectively.

As illustratively shown in FIG. 3A, the gate portion GP11 crosses over and is coupled to each of the source/drain structures SDN1 and SDP1. The gate portion GP12 crosses over and is coupled to the source/drain structure SDN2. The gate portion GP13 crosses over and is coupled to the source/drain structure SDN3. The gate portion GP14 crosses over and is coupled to each of the source/drain structures SDN4 and SDP5. The gate portion GP21 crosses over and is coupled to the source/drain structure SDN1. The gate portion GP22 crosses over and is coupled to each of the source/drain structures SDP3 and SDN2. The gate portion GP23 crosses over and is coupled to each of the source/drain structures SDP4 and SDN3. The gate portion GP24 crosses over and is coupled to the source/drain structures SDN4.

Similarly, the gate portion GP41 crosses over and is coupled to each of the source/drain structures SDN1 and SDP2. The gate portion GP42 crosses over and is coupled to the source/drain structure SDN2. The gate portion GP43 crosses over and is coupled to the source/drain structure SDN3. The gate portion GP44 crosses over and is coupled to each of the source/drain structures SDN4 and SDP6. The gate portion GP31 crosses over and is coupled to the source/drain structure SDN1. The gate portion GP32 crosses over and is coupled to each of the source/drain structures SDP3 and SDN2. The gate portion GP33 crosses over and is coupled to each of the source/drain structures SDP4 and SDN3. The gate portion GP34 crosses over and is coupled to the source/drain structures SDN4.

As illustratively shown in FIG. 3A, the conductive features MD1-MD5 are arranged in order and separated from each other along the Y direction. The gate structure PO1 is located between the conductive features MD1 and MD2. The gate structure PO2 is located between the conductive features MD2 and MD3. The gate structure PO3 is located between the conductive features MD3 and MD4. The gate structure PO4 is located between the conductive features MD4 and MD5.

Along the X direction, each of the conductive features MD6, MD9, MD14, MD19 and MD23 is aligned with the conductive feature MD1, each of the conductive features MD10, MD15 and MD20 is aligned with the conductive feature MD2, each of the conductive features MD8, MD11, MD18 and MD24 is aligned with the conductive feature MD3, each of the conductive features MD12, MD16 and MD21 is aligned with the conductive feature MD4, and each of the conductive features MD7, MD13, MD17, MD22 and MD25 is aligned with the conductive feature MD5.

Each of the conductive features MD1-MD5 is overlapped with and coupled to the source/drain structure SDN1. Each of the conductive features MD6 and MD2 is overlapped with and coupled to the source/drain structure SDP1. Each of the conductive features MD4 and MD7 is overlapped with and coupled to the source/drain structure SDP2. Each of the conductive features MD10, MD8 and MD12 is overlapped with and coupled to the source/drain structure SDP3. Each of the conductive features MD9, MD10, MD11, MD12 and MD13 is overlapped with and coupled to the source/drain structure SDN2. Each of the conductive features MD14, MD15, MD11, MD16 and MD17 is overlapped with and coupled to the source/drain structure SDN3. Each of the conductive features MD15, MD18 and MD16 is overlapped with and coupled to the source/drain structure SDP4. Each of the conductive features MD19 and MD20 is overlapped with and coupled to the source/drain structure SDP5. Each of the conductive features MD21 and MD22 is overlapped with and coupled to the source/drain structure SDP6. Each of the conductive features MD23, MD20, MD24, MD21 and MD25 is overlapped with and coupled to the source/drain structure SDN4.

As illustratively shown in FIG. 3A, the via structures VG1-VG8 and VD1-VD17 are coupled to the gate portions GP21, GP31, GP12, GP42, GP13, GP43, GP24, GP34 and the conductive features MD1, MD5, MD3, MD6, MD7, MD8, MD9, MD13, MD11, MD14, MD17, MD18, MD19, MD22, MD24, MD23, MD25, respectively.

Each of the via structures VD1 and VD2 is disposed directly above the cut region CMG1. Each of the via structures VG1 and VG2 is disposed directly above the source/drain structure SDN1. Each of the via structures VG3 and VG4 is disposed directly above the source/drain structure SDN2. Each of the via structures VG5 and VG6 is disposed directly above the source/drain structure SDN3. Each of the via structures VG7 and VG8 is disposed directly above the source/drain structure SDN4. Each of the via structures VD16 and VD17 is disposed directly above the cut region CMG9. The via structure VD9 is disposed directly above the cut region CMG5.

Alternatively stated, along the X direction, each of the via structures VG1 and VG2 is disposed between the cut regions CMG1 and CMG2, and each of the via structures VG7 and VG8 is disposed between the cut regions CMG8 and CMG9. Accordingly, along the Y direction, the via structures VG1 and VG2 are not aligned with the via structures VD1 and VD2, and the via structures VG7 and VG8 are not aligned with the via structures VD16 and VD17.

As illustratively shown in FIG. 3A, the conductive feature BCT1 is configured to couple the source/drain structure SDP1 to the gate portion GP22. The conductive feature BCT2 is configured to couple the source/drain structure SDP2 to the gate portion GP32. The conductive feature BCT3 is configured to couple the source/drain structure SDP3 to the gate portion GP11. The conductive feature BCT4 is configured to couple the source/drain structure SDP3 to the gate portion GP41. The conductive feature BCT5 is configured to couple the source/drain structure SDP4 to the gate portion GP14. The conductive feature BCT6 is configured to couple the source/drain structure SDP4 to the gate portion GP44. The conductive feature BCT7 is configured to couple the source/drain structure SDP5 to the gate portion GP23. The conductive feature BCT8 is configured to couple the source/drain structure SDP6 to the gate portion GP33.

Referring to FIG. 2 and FIG. 3A, the memory cells MC[n]-MC[n+3] are implemented by the structure shown in FIG. 3A. Along the X direction, the memory cells MC[n] and MC[n+1] are adjacent with each other, and the memory cells MC[n+2] and MC[n+3] are adjacent with each other. Along the Y direction, the memory cells MC[n] and MC[n+2] are adjacent with each other, and the memory cells MC[n+1] and MC[n+3] are adjacent with each other.

The control terminals of the switches PD23 and PU23 are implemented by the gate portion GP11. The control terminals of the switches PD13 and PU13 are implemented by the gate portion GP22. The control terminals of the switches PG13 and PG23 are implemented by the gate portions GP12 and GP21, respectively. The control terminals of the switches PD22 and PU22 are implemented by the gate portion GP23. The control terminals of the switches PD12 and PU12 are implemented by the gate portion GP14. The control terminals of the switches PG12 and PG22 are implemented by the gate portions PG24 and PG13, respectively.

Similarly, the control terminals of the switches PD21 and PU21 are implemented by the gate portion GP41. The control terminals of the switches PD12 and PU12 are implemented by the gate portion GP32. The control terminals of the switches PG11 and PG21 are implemented by the gate portions GP42 and GP31, respectively. The control terminals of the switches PD20 and PU20 are implemented by the gate portion GP33. The control terminals of the switches PD10 and PU10 are implemented by the gate portion GP44. The control terminals of the switches PG10 and PG20 are implemented by the gate portions PG34 and PG43, respectively.

On the other hand, the source/drain terminals of the switches PD23, PG23, PG21 and PD21 are implemented by the source/drain structure SDN1. The source/drain terminals of the switch PU23 is implemented by the source/drain structure SDP1. The source/drain terminals of the switch PU21 is implemented by the source/drain structure SDP2. The source/drain terminals of the switches PU13 and PU11 are implemented by the source/drain structure SDP3. The source/drain terminals of the switches PD13, PG13, PG11 and PD11 are implemented by the source/drain structure SDN2.

Similarly, the source/drain terminals of the switches PD22, PG22, PG20 and PD20 are implemented by the source/drain structure SDN3. The source/drain terminals of the switch PU12 is implemented by the source/drain structure SDP5. The source/drain terminals of the switch PU10 is implemented by the source/drain structure SDP6. The source/drain terminals of the switches PU21 and PU20 are implemented by the source/drain structure SDP4. The source/drain terminals of the switches PD11, PG11, PG10 and PD10 are implemented by the source/drain structure SDN4. The nodes N21-N28 corresponds to the conductive features BCT8, BCT6, BCT4, BCT2, BCT7, BCT5, BCT3 and BCT1, respectively.

In some embodiments, each of the conductive features MD1, MD5, MD11, MD23 and MD25 is configured to receive the reference voltage signal VSS. Each of the conductive features MD6, MD7, MD8, MD18, MD19 and MD22 is configured to receive the reference voltage signal CVDD. The conductive features MD3 and MD24 are configured to receive the bit line signals BL[n] and BL[n+1], respectively. Each of the conductive features MD9 and MD13 is configured to receive the bit line signal BLB[n]. Each of the conductive features MD10 and MD17 is configured to receive the bit line signal BLB[n+1]. Each of the via structures VG1 and VG3 is configured to receive the word line signal WL[n+3]. Each of the via structures VG2 and VG4 is configured to receive the word line signal WL[n+1]. Each of the via structures VG5 and VG7 is configured to receive the word line signal WL[n+2]. Each of the via structures VG6 and VG8 is configured to receive the word line signal WL[n].

FIG. 3B is a schematic diagram of cross-sectional view along a line L31 of the memory device 300 shown in FIG. 3A, illustrated in accordance with some embodiments of the present disclosure. In FIG. 3B, the Y direction points into the paper. Referring to FIG. 3A and FIG. 3B, the memory device 300 further includes gate portions MG1-MG4. The source/drain structures SDN1, SDP1, SDP3, SDN2, SDP4, SDP5 and SDN4 include channel structures CPN1, CPP1, CPP2, CPN2, CPN3, CPP3, CPP4 and CPN4, respectively.

As illustratively shown in FIG. 3B, the gate portions GP21-GP24 are coupled to and disposed above the gate portions MG1-MG4, respectively. The gate portion MG1 surrounds the channel structure CPN1. The gate portion MG2 surrounds each of the channel structures CPP1, CPP2 and CPN2. The gate portion MG3 surrounds each of the channel structures CPP3, CPP4 and CPN3. The gate portion MG4 surrounds the channel structure CPN4.

The cut regions CMG1, CMG2, CMG5, CMG8 and CMG9 are elongated along the Z direction to separate the gate portions MG1-MG4 from each other. A height of the cut regions CMG1, CMG2, CMG5, CMG8 and CMG9 is larger than a summation of a height of the gate portions MG1-MG4 plus a height of the gate portions GP21-GP24.

FIG. 3C is a schematic diagram of cross-sectional view along a line L32 of the memory device 300 shown in FIG. 3A, illustrated in accordance with some embodiments of the present disclosure. In FIG. 3C, the Y direction points into the paper. Referring to FIG. 3A and FIG. 3C, the source/drain structures SDN1, SDP1, SDN2, SDN3, SDP5 and SDN4 include doped structures DPN1, DPP1, DPN2, DPN3, DPP2 and DPN4, respectively. In some embodiments, the doped structures DPN1-DPN4 are formed with first type of epitaxy, such as N-type epitaxy, and the doped structures DPP1-DPP2 are formed with second type of epitaxy, such as P-type epitaxy.

As illustratively shown in FIG. 3C, along the Z direction, the conductive features MD1, MD9, MD14 and MD23 are disposed above the cut regions CMG1, CMG3, CMG6 and CMG9, respectively. A height of the cut region CMG5 is larger than a height of the cut regions CMG1, CMG3, CMG6 and CMG9. The memory device 300 further includes cut regions CEO1 and CEO2. The cut region CEO1 is disposed between the conductive feature MD6 and MD9. The cut region CEO2 is disposed between the conductive feature MD14 and MD19.

In some embodiments, material of the cut regions CEO1 and CEO2 is same as the material of the cut regions CMG1, CMG3, CMG5, CMG6 and CMG9. Alternatively stated, the cut regions CEO1 and CEO2 can be formed with nitride, such as silicon nitride.

FIG. 3D is a schematic diagram of further details of the memory device 300 shown in FIG. 3A, illustrated in accordance with some embodiments of the present disclosure. For simplicity, some labels shown in FIG. 3A are not shown in FIG. 3D, such as the labels of source/drain structures SDN1-SDN4, SDP1-SDP6 and gate portions GP11-GP14, GP21-GP24, GP31-GP34, GP41-GP44.

As illustratively shown in FIG. 3D, the memory device 300 further includes conductive features M0A1-M0A6 and M0B1-M0B8 which are disposed above the structure shown in FIG. 3A along the Z direction. The conductive features M0B1, M0A1, M0B2, M0A2, M0B3, M0A3, M0B5, M0A4, M0B6, M0A5, M0B8, M0A6 and M0B9 are arranged in order and separated from each other along the X direction. Along the Y direction, the conductive features M0B4 and M0B7 are aligned with the conductive features M0B3 and M0B6, respectively.

In some embodiments, the conductive features M0A1-M0A6 and M0B1-M0B8 are disposed in metal-zero (M0) layer. In some embodiments, along the Z direction, a height of the conductive features M0B1-M0B8 is larger than a height of the conductive features M0A1-M0A6.

As illustratively shown in FIG. 3D, the conductive features M0B1 and M0A1 cross over each of the conductive feature MD1 and MD5. The conductive feature M0B2 crosses over the conductive feature MD3. The conductive feature M0A2 is overlapped with each of the conductive features MD6-MD8. The conductive features M0B3, M0B5, M0B6, M0B4 and M0B7 cross over the conductive features MD9, MD11, MD14, MD13 and MD17, respectively. The conductive feature M0A3 crosses over each of the conductive features MD9 and MD13. The conductive feature M0A4 crosses over each of the conductive features MD14 and MD17. The conductive features M0B9 and M0A6 cross over each of the conductive feature MD23 and MD25. The conductive feature M0B8 crosses over the conductive feature MD24. The conductive feature M0A5 is overlapped with each of the conductive features MD19, MD18 and MD22. It is noted that the conductive features M0B1, M0B5 and M0B9 are overlapped with the cut regions CMG1, CMG5 and CMG9, respectively.

In some embodiments, the memory device 300 further includes cut regions CM0A1-CM0A3. Each of the cut regions CM0A1-CM0A3 is disposed between the gate structures PO2 and PO3. The cut region CM0A1 is configured to cut the conductive feature M0A1 into conductive portions M0AP1 and M0AP2. The cut region CM0A2 is configured to cut the conductive feature M0A3 into conductive portions M0AP3 and M0AP4, and cut the conductive feature M0A4 into conductive portions M0AP5 and M0AP6. The cut region CM0A3 is configured to cut the conductive feature M0A6 into conductive portions M0AP7 and M0AP8.

Referring to FIG. 2, FIG. 3A and FIG. 3D, the conductive features M0B1, M0B5 and M0B9 are configured to transmit the reference voltage signal VSS through the via structures VD1, VD2, VD9, VD16 and VD17 to the conductive features MD1, MD5, MD11, MD23 and MD25. The conductive features M0A1 and M0A5 are configured to transmit the reference voltage signal CVDD through the via structures VD4, VD6, VD5 and VD12-VD14 to the conductive features MD6-MD8, MD18, MD19 and MD22.

The conductive portions M0AP1 and M0AP3 are configured to transmit the word line signal WLS[n+3] through the via structures VG1 and VG3 to the gate portions GP21 and GP12. The conductive portions M0AP2 and M0AP4 are configured to transmit the word line signal WLS[n+1] through the via structures VG2 and VG4 to the gate portions GP31 and GP42. The conductive portions M0AP5 and M0AP7 are configured to transmit the word line signal WLS[n+2] through the via structures VG5 and VG7 to the gate portions GP13 and GP24. The conductive portions M0AP6 and M0AP8 are configured to transmit the word line signal WLS[n] through the via structures VG6 and VG8 to the gate portions GP43 and GP34.

The conductive feature M0B2 is configured to transmit the bit line signal BL[n] through the via structure VD3 to the conductive feature MD3. The conductive features M0B3 and M0B4 are configured to transmit the bit line signal BLB[n] through the via structures VD7 and VD8 to the conductive feature MD9 and MD13. The conductive feature M0B8 is configured to transmit the bit line signal BL[n+1] through the via structure VD15 to the conductive feature MD24. The conductive features M0B6 and M0B7 are configured to transmit the bit line signal BLB[n+1] through the via structures VD11 and VD10 to the conductive feature MD14 and MD17.

As illustratively shown in FIG. 3D, the memory device 300 further includes via structures V01-V08. Along the Z direction, the via structures V01-V08 are disposed above and coupled to the conductive portions M0AP1-M0AP8, respectively, to transmit corresponding word line signals.

FIG. 3E is a schematic diagram of further details of the memory device 300 shown in FIG. 3D, illustrated in accordance with some embodiments of the present disclosure. For simplicity, some labels shown in FIG. 3D are not shown in FIG. 3E, such as the labels of the conductive features MD1-MD24.

As illustratively shown in FIG. 3E, the memory device 300 further includes conductive features M1W0-M1W3, M1B1-M1B6 and M1S1-M1S5 which are disposed above the structure shown in FIG. 3D along the Z direction. In some embodiments, the conductive features M1W0-M1W3, M1B1-M1B6 and M1S1-M1S5 are disposed in metal-one (M1) layer which is above the M0 layer.

The conductive features M1S1, M1W3, M1B2, M1W1 and M1S3 are arranged in order and separated from each other along the Y direction. Along the X direction, the conductive features M1B1, M1B4 and M1S4 are aligned with the conductive feature M1S1. The conductive feature M1W2 is aligned with the conductive feature M1W3. The conductive features M1S2 and M1B5 are aligned with the conductive feature M1B2. The conductive feature M1W0 is aligned with the conductive feature M1W1. The conductive features M1B3, M1B6 and M1S5 are aligned with the conductive feature M1S3.

As illustratively shown in FIG. 3E, the conductive features M1S1 and M1S3 cross over each of the conductive features M0B1 and M0A2. The conductive feature M1S2 crosses over each of the conductive features M0A5 and M0A2. The conductive feature M1S3 crosses over each of the conductive features M0B1 and M0A2. The conductive features M1S4 and M1S5 crosses over each of the conductive features M0B9 and M0A5.

The conductive feature M1B1 crosses over each of the conductive features M0B2 and M0A3. The conductive feature M1B4 crosses over each of the conductive features M0B6 and M0A4. The conductive feature M1B3 crosses over each of the conductive features M0B4 and M0A3. The conductive feature M1B6 crosses over each of the conductive features M0B7 and M0A4. The conductive feature M1B2 crosses over each of the conductive features M0B2 and M0A1. The conductive feature M1B5 crosses over each of the conductive features M0B8 and M0A6. The conductive features M1W0 and M1W2 cross over each of the conductive features M0A4 and M0A6. The conductive features M1W1 and M1W3 cross over each of the conductive features M0A1 and M0A3.

Referring to FIG. 2 to FIG. 3E, the conductive features M1S1-M1S5 are configured to transmit the reference voltage signal VSS to the conductive features M0B1, M0B5 and M0B9. The conductive feature M1B2 is configured to transmit the bit line signal BL[n] to the conductive feature M0B2. The conductive feature M1B5 is configured to transmit the bit line signal BL[n+1] to the conductive feature M0B8. The conductive features M1B1 and M1B3 are configured to transmit the bit line signal BLB[n] to the conductive features M0B3 and M0B4. The conductive features M1B4 and M1B6 are configured to transmit the bit line signal BLB[n+1] to the conductive features M0B6 and M0B7.

The conductive feature M1W3 is configured to transmit the word line signal WLS[n+3] through the via structures V01 and V03 to the conductive portions M0AP1 and M0AP3. The conductive feature M1W2 is configured to transmit the word line signal WLS[n+2] through the via structures V05 and V07 to the conductive portions M0AP5 and M0AP7. The conductive feature M1W1 is configured to transmit the word line signal WLS[n+1] through the via structures V02 and V04 to the conductive portions M0AP2 and M0AP4. The conductive feature M1W0 is configured to transmit the word line signal WLS[n] through the via structures V06 and V08 to the conductive portions M0AP6 and M0AP8.

FIG. 3F is a schematic diagram of further details of the memory device 300 shown in FIG. 3E, illustrated in accordance with some embodiments of the present disclosure. As illustratively shown in FIG. 3F, the memory device 300 further includes conductive features M2W0-M2W3, M2B1-M2B4, M2S1-M2S2 and via structures V1W0-V1W3, V1B1-V1B6 and V1S1-V1S6 which are disposed above the structure shown in FIG. 3E along the Z direction. In some embodiments, the conductive features M2W0-M2W3, M2B1-M2B4 and M2S1-M2S2 are disposed in metal-two (M2) layer which is above the M1 layer.

The conductive features M2B1, M2W1, M2S1, M2W3, M2B2, M2B3, M2W0, M2S2, M2W2 and M2B4 are arranged in order and separated from each other along the X direction. The conductive features M2B1 and M2S1 cross over each of the conductive features M1S1 and M1S3. The conductive feature M2W1 crosses over each of the conductive features M1W1 and M1S3. The conductive feature M2W3 crosses over each of the conductive features M1W3 and M1W1. The conductive feature M2B2 crosses over each of the conductive features M1B1 and M1B3. The conductive feature M2B3 crosses over each of the conductive features M1B4 and M1B6. The conductive feature M2W0 crosses over each of the conductive features M1W2 and M1W0. The conductive feature M2W2 crosses over each of the conductive features M1S4 and M1W2. The conductive features M2B4 and M2S2 cross over each of the conductive features M1S4 and M1S5.

Referring to FIG. 2 to FIG. 3F, the conductive feature M2B1 is configured to transmit the bit line signal BL[n] through the via structure V1B1 to the conductive feature M1B2. The conductive feature M2W1 is configured to transmit the word line signal WLS[n+1] through the via structure V1W1 to the conductive feature M1W1. The conductive feature M2S1 is configured to transmit the reference voltage signal VSS through the via structures V1S1-V1S3 to the conductive features M1S1-M1S3. The conductive feature M2W3 is configured to transmit the word line signal WLS[n+3] through the via structure V1W3 to the conductive feature M1W3. The conductive feature M2B2 is configured to transmit the bit line signal BLB[n] through the via structures V1B2 and V1B3 to the conductive features M1B1 and M1B3.

Similarly, the conductive feature M2B4 is configured to transmit the bit line signal BL[n+1] through the via structure V1B6 to the conductive feature M1B5. The conductive feature M2W2 is configured to transmit the word line signal WLS[n+2] through the via structure V1W2 to the conductive feature M1W2. The conductive feature M2S2 is configured to transmit the reference voltage signal VSS through the via structures V1S4-V1S6 to the conductive features M1S4, M1S2 and M1S5. The conductive feature M2W0 is configured to transmit the word line signal WLS[n] through the via structure V1W0 to the conductive feature M1W0. The conductive feature M2B3 is configured to transmit the bit line signal BLB[n+1] through the via structures V1B4 and V1B5 to the conductive features M1B4 and M1B6.

In some embodiments, the conductive features M2W0-M2W3 are referred to as landing pads of word line connection. Along the Y direction, a length of each of the conductive features M2W0-M2W3 is shorter than a length of each of the conductive features M2B1-M2B4.

FIG. 3G is a schematic diagram of further details of the memory device 300 shown in FIG. 3F, illustrated in accordance with some embodiments of the present disclosure. As illustratively shown in FIG. 3G, the memory device 300 further includes conductive features M30-M33 and via structures V20-V23 which are disposed above the structure shown in FIG. 3F along the Z direction. In some embodiments, the conductive features M30-M33 are disposed in metal-three (M3) layer which is above the M2 layer.

Along the Y direction, each of the conductive features M30 and M33 is disposed between the conductive features M31 and M32. The conductive features M30 and M33 are aligned with each other along the X direction. The conductive features M31 and M32 cross over each of the conductive features M2B1 and M2B4. The conductive feature M33 crosses over each of the conductive features M2W1 and M2W3, and is overlapped with the conductive feature M2B2. The conductive feature M30 crosses over each of the conductive features M2W0 and M2W2, and is overlapped with the conductive feature M2B4. It is noted that the conductive feature M32 crosses over each of the memory cells MC[n+2] and MC[n+3], and the conductive feature M31 crosses over each of the memory cells MC[n] and MC[n+1].

Referring to FIG. 2 to FIG. 3G, the conductive feature M30 is configured to transmit the word line signal WLS[n] through the via structure V20 to the conductive feature M2W0. The conductive feature M31 is configured to transmit the word line signal WLS[n+1] through the via structure V21 to the conductive feature M2W1. The conductive feature M32 is configured to transmit the word line signal WLS[n+2] through the via structure V22 to the conductive feature M2W2. The conductive feature M33 is configured to transmit the word line signal WLS[n+3] through the via structure V23 to the conductive feature M2W3.

In some embodiments, the conductive features M30 and M33 are referred to as landing pads of word line connection. Along the X direction, a length of each of the conductive features M30 and M33 is shorter than a length of each of the conductive features M31 and M32.

FIG. 3H is a schematic diagram of further details of the memory device 300 shown in FIG. 3G, illustrated in accordance with some embodiments of the present disclosure. As illustratively shown in FIG. 3H, the memory device 300 further includes conductive features M40, M43, M50, M53, M5S and via structures V30, V33, V40, V43 which are disposed above the structure shown in FIG. 3G along the Z direction. In some embodiments, the conductive features M40 and M43 are disposed in metal-four (M4) layer which is above the M3 layer, and the conductive features M50 and M53 are disposed in metal-five (M5) layer which is above the M4 layer.

The conductive feature M40 crosses over each of the conductive features M43 and M4. The conductive feature M43 crosses over each of the conductive features M32 and M33. The conductive feature M50 crosses over each of the conductive features M40 and M43, and is overlapped with the conductive feature M31. The conductive feature M53 crosses over the conductive feature M43, and is overlapped with the conductive feature M32. It is noted that the conductive feature M53 crosses over each of the memory cells MC[n+2] and MC[n+3], and the conductive feature M30 crosses over each of the memory cells MC[n] and MC[n+1].

Referring to FIG. 2 to FIG. 3H, the conductive feature M40 is configured to transmit the word line signal WLS[n] through the via structure V30 to the conductive feature M30. The conductive feature M43 is configured to transmit the word line signal WLS[n+3] through the via structure V33 to the conductive feature M33. The conductive feature M50 is configured to transmit the word line signal WLS[n] through the via structure V40 to the conductive feature M40. The conductive feature M53 is configured to transmit the word line signal WLS[n+3] through the via structure V43 to the conductive feature M43. The conductive feature M5S is configured to transmit the reference voltage signal VSS. In some embodiments, the conductive features M40 and M43 are referred to as landing pads of word line connection, and the conductive feature M5S is referred to as a ground plane.

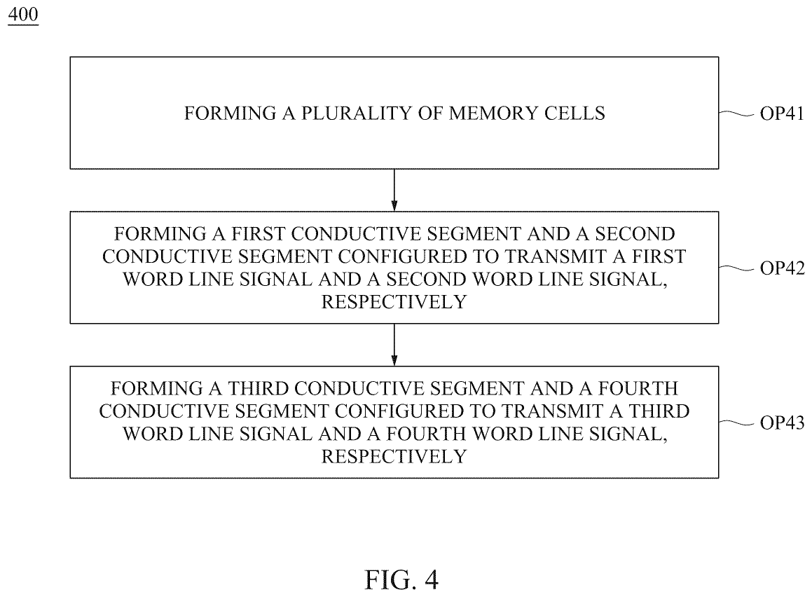

FIG. 4 is a flowchart diagram of a method 400 for fabricating the memory devices described above, illustrated in accordance with some embodiments of the present disclosure. The method 400 includes operations OP41-OP43.

During the operation OP41, a plurality of memory cells are formed. For example, the memory cells MCS shown in FIG. 1 or the memory cells MC[n]-MC[n+3] shown in FIG. 3A are formed.

During the operation OP42, a first conductive feature and a second conductive feature are formed. The first conductive feature and the second conductive feature are configured to transmit a first word line signal and a second word line signal, respectively. For example, the conductive features M31 and M32 shown in FIG. 3H are formed. The conductive features M31 and M32 are configured to transmit the word line signals WLS[n+1] and WLS[n+2], respectively.

During the operation OP43, a third conductive feature and a fourth conductive feature are formed. The third conductive feature and the fourth conductive feature are configured to transmit a third word line signal and a fourth word line signal, respectively. For example, the conductive features M50 and M53 shown in FIG. 3H are formed. The conductive features M50 and M53 are configured to transmit the word line signals WLS[n] and WLS[n+3], respectively.

In some embodiments, a first memory cell, a second memory cell, a third memory cell and a fourth memory cell of the plurality of memory cells are configured to receive the third word line signal, the first word line signal, the second word line signal and the fourth word line signal, respectively. The third conductive feature and the fourth conductive feature are overlapped with the first conductive feature and the second conductive feature, respectively.

For example, the memory cells MC[n]-MC[n+3] are configured to receive the word line signals WLS[n] and WLS[n+3], respectively. The conductive features M50 and M53 are overlapped with the conductive features M31 and M32, respectively.

In some embodiments, the method 400 further includes forming a fifth conductive feature and a sixth conductive feature between the first conductive feature and the second conductive feature. For example, the conductive features M30 and M33 are formed between the conductive features M31 and M32.

In some embodiments, the method 400 further includes forming a seventh conductive feature crossing over the fifth conductive feature and configured to transmit the third word line signal, and forming an eighth conductive feature crossing over the sixth conductive feature and configured to transmit the fourth word line signal. For example, the conductive feature M40 crossing over the conductive feature M30 and configured to transmit the word line signal WLS[n] is formed, and the conductive feature M43 crossing over the conductive feature M33 and configured to transmit the word line signal WLS[n+3] is formed.

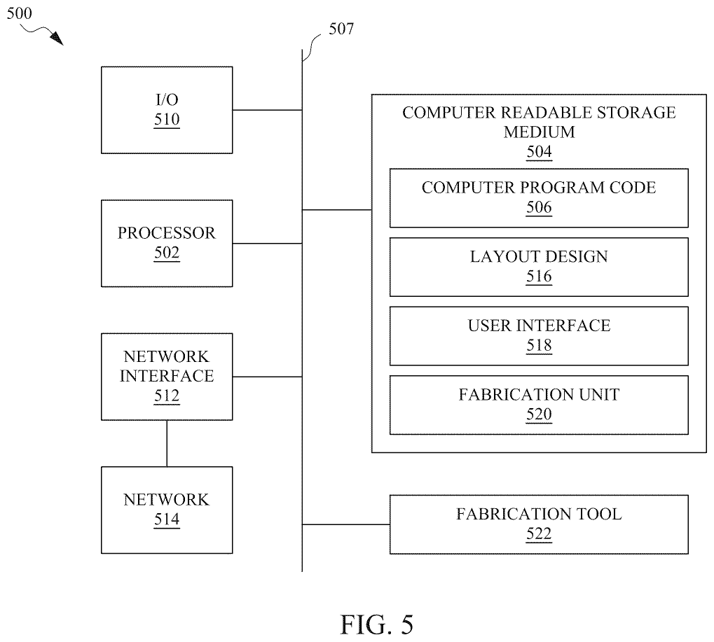

FIG. 5 is a schematic view of a system 500 for designing and manufacturing at least one of the semiconductor devices as described herein, in accordance with some embodiments of the present disclosure. The system 500 generates or places one or more IC layout designs corresponding to at least one of the semiconductor devices as described herein. In some embodiments, the system 500 manufactures one or more semiconductor devices based on the one or more IC layout designs, as described herein. The system 500 includes a hardware processor 502 and a non-transitory, computer readable storage medium 504 encoded with, e.g., storing, the computer program code 506, e.g., a set of executable instructions. The computer readable storage medium 504 is configured for interfacing with manufacturing machines for producing the semiconductor device. The processor 502 is electrically coupled to the computer readable storage medium 504 by a bus 507. The processor 502 is also electrically coupled to an I/O interface 510 by the bus 507. A network interface 512 is also electrically connected to the processor 502 by the bus 507. Network interface 512 is connected to a network 514, so that the processor 502 and the computer readable storage medium 504 are capable of connecting to external elements via network 514. The processor 502 is configured to execute the computer program code 506 encoded in the computer readable storage medium 504 in order to cause the system 500 designing and manufacturing at least one of the semiconductor devices as described herein.

In some embodiments, the processor 502 is a central processing unit (CPU), a multi-processor, a distributed processing system, an application specific integrated circuit (ASIC), and/or a suitable processing unit.

In some embodiments, the computer readable storage medium 504 is an electronic, magnetic, optical, electromagnetic, infrared, and/or a semiconductor system (or apparatus or device). For example, the computer readable storage medium 504 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 504 includes a compact disk-read only memory (CD-ROM), a compact disk-read/write (CD-R/W), and/or a digital video disc (DVD).

In some embodiments, the storage medium 504 also stores information needed for designing and manufacturing at least one of the semiconductor devices as described herein, such as layout design 516, user interface 518, fabrication unit 520, and/or a set of executable instructions to designing and manufacturing at least one of the semiconductor devices as described herein.

In some embodiments, the storage medium 504 stores instructions (e.g., the computer program code 506) for interfacing with manufacturing machines. The instructions (e.g., the computer program code 506) enable the processor 502 to generate manufacturing instructions readable by the manufacturing machines to effectively implement the semiconductor devices as described herein.

The system 500 includes the I/O interface 510. The I/O interface 510 is coupled to external circuitry. In some embodiments, the I/O interface 510 includes a keyboard, keypad, mouse, trackball, trackpad, and/or cursor direction keys for communicating information and commands to the processor 502.

The system 500 also includes the network interface 512 coupled to the processor 502. The network interface 512 allows the system 500 to communicate with the network 514, to which one or more other computer systems are connected. The network interface 512 includes wireless network interfaces such as BLUETOOTH, WIFI, WIMAX, GPRS, or WCDMA; or wired network interface such as ETHERNET, USB, or IEEE-13154. In some embodiments, the designing and manufacturing of at least one of the semiconductor devices as described herein is implemented in two or more systems 500, and information such as layout design, user interface and fabrication unit are exchanged between different systems 500 by the network 514.

The system 500 is configured to receive information related to a layout design through the I/O interface 510 or network interface 512. The information is transferred to the processor 502 by the bus 507 to determine a layout design for producing an IC. The layout design is then stored in the computer readable medium 504 as the layout design 516. The system 500 is configured to receive information related to a user interface through the I/O interface 510 or network interface 512. The information is stored in the computer readable medium 504 as the user interface 518. The system 500 is configured to receive information related to a fabrication unit through the I/O interface 510 or network interface 512. The information is stored in the computer readable medium 504 as the fabrication unit 520. In some embodiments, the fabrication unit 520 includes fabrication information utilized by the system 500.

In some embodiments, the designing and manufacturing of at least one of the semiconductor devices as described herein is implemented as a standalone software application for execution by a processor. In some embodiments, the designing and manufacturing of at least one of the semiconductor devices as described herein is implemented as a software application that is a part of an additional software application. In some embodiments, the designing and manufacturing of at least one of the semiconductor devices as described herein is implemented as a plug-in to a software application. In some embodiments, the designing and manufacturing of at least one of the semiconductor devices as described herein is implemented as a software application that is a portion of an EDA tool. In some embodiments, the designing and manufacturing of at least one of the semiconductor devices as described herein is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, at least one of the semiconductor devices as described herein is implemented by a manufacturing device to manufacture an integrated circuit using a set of masks manufactured based on one or more layout designs generated by the system 500. In some embodiments, the system 500 includes a manufacturing device (e.g., fabrication tool 522) to manufacture an integrated circuit using a set of masks manufactured based on one or more layout designs of the present disclosure.

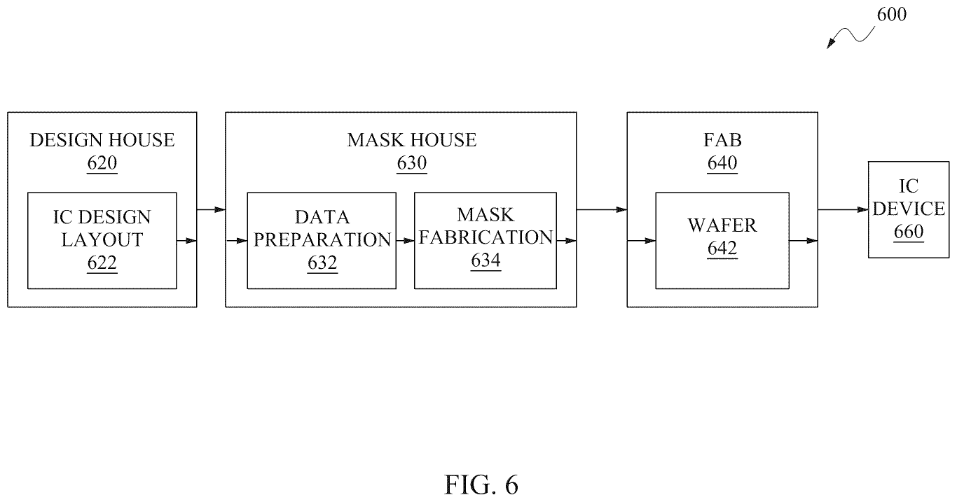

FIG. 6 is a block diagram of an integrated circuit (IC)/semiconductor device manufacturing system 600, and an IC manufacturing flow associated therewith, in accordance with some embodiments of the present disclosure. Referring to FIG. 4 and FIG. 6, the method 400 is performed by the IC manufacturing system 600 in some embodiments.

In FIG. 6, the IC manufacturing system 600 includes entities, such as a design house 620, a mask house 630, and an IC manufacturer/fabricator (“fab”) 640, that interact with one another in the design, development, and manufacturing cycles and/or services related to manufacturing an IC device (semiconductor device) 660 including at least one of the semiconductor devices as described herein. The entities in system 600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 620, mask house 630, and IC fab 640 is owned by a single company. In some embodiments, two or more of design house 620, mask house 630, and IC fab 640 coexist in a common facility and use common resources.

The design house (or design team) 620 generates an IC design layout 622. The IC design layout 622 includes various geometrical patterns designed for the IC device 660. The geometrical patterns correspond to patterns of metal, oxide, or semiconductor layers that make up the various components of the IC device 660 to be fabricated. The various layers combine to form various IC features. For example, a portion of the IC design layout 622 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 620 implements a proper design procedure to form the IC design layout 622. The design procedure includes one or more of logic design, physical design or place and route. The IC design layout 622 is presented in one or more data files having information of the geometrical patterns. For example, the IC design layout 622 can be expressed in a GDSII file format or DFII file format.

The mask house 630 includes mask data preparation 632 and mask fabrication 634. The mask house 630 uses the IC design layout 622 to manufacture one or more masks to be used for fabricating the various layers of the IC device 660 according to the IC design layout 622. The mask house 630 performs the mask data preparation 632, where the IC design layout 622 is translated into a representative data file (“RDF”). The mask data preparation 632 provides the RDF to the mask fabrication 634. The mask fabrication 634 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 632 to comply with particular characteristics of the mask writer and/or requirements of the IC fab 640. In FIG. 6, the mask data preparation 632 and mask fabrication 634 are illustrated as separate elements. In some embodiments, the mask data preparation 632 and mask fabrication 634 can be collectively referred to as mask data preparation.

In some embodiments, the mask data preparation 632 includes optical proximity correction (OPC) which uses lithography enhancement techniques to compensate for image errors, such as those that can arise from diffraction, interference, other process effects and the like. OPC adjusts the IC design layout 622. In some embodiments, the mask data preparation 632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 632 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 634, which may undo part of the modifications performed by OPC in order to meet mask creation rules.

In some embodiments, the mask data preparation 632 includes lithography process checking (LPC) that simulates processing that will be implemented by the IC fab 640 to fabricate the IC device 660. LPC simulates this processing based on the IC design layout 622 to create a simulated manufactured device, such as the IC device 660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 622.

It should be understood that the above description of the mask data preparation 632 has been simplified for the purposes of clarity. In some embodiments, the mask data preparation 632 includes additional features such as a logic operation (LOP) to modify the IC design layout according to manufacturing rules. Additionally, the processes applied to the IC design layout 622 during the mask data preparation 632 may be executed in a variety of different orders.

After the mask data preparation 632 and during mask fabrication 634, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 634 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 640 is an IC fabrication entity that includes one or more manufacturing facilities for the fabrication of a variety of different IC products. In some embodiments, the IC fab 640 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 640 uses the mask (or masks) fabricated by the mask house 630 to fabricate the IC device 660. Thus, the IC fab 640 at least indirectly uses the IC design layout 622 to fabricate the IC device 660. In some embodiments, a semiconductor wafer is fabricated by the IC fab 640 using the mask (or masks) to form the IC device 660. The semiconductor wafer 642 includes a silicon substrate or other proper substrate having material layers formed thereon. Semiconductor wafer further includes one or more of various doped regions, dielectric features, multilevel interconnects, and the like (formed at subsequent manufacturing steps).

Also disclosed is a device. The device includes a first memory cell, a second memory cell, a first conductive feature and a second conductive feature. The first memory cell is configured to receive a first word line signal. The second memory cell is adjacent with the first memory cell, and configured to receive a second word line signal. The first conductive feature crosses over each of the first memory cell and the second memory cell, and is configured to transmit the first word line signal. The second conductive feature crosses over each of the first memory cell and the second memory cell, is overlapped with the first conductive feature, and is configured to transmit the second word line signal.

Also disclosed is a device. The device includes a first source/drain structure, a second source/drain structure, a first gate structure, a first via structure, a second via structure and a third via structure. The second source/drain structure is separated from the first source/drain structure along a first direction. The first gate structure crosses over each of the first source/drain structure and the second source/drain structure. The first via structure is configured to transmit a first word line signal to the first gate structure. The second via structure is configured to transmit a reference voltage signal to the first source/drain structure. The third via structure is configured to transmit the reference voltage signal to the second source/drain structure. The first via structure is disposed between the second via structure and the third via structure along the first direction.

Also disclosed is a method. The method includes: forming a plurality of memory cells; forming a first conductive feature and a second conductive feature configured to transmit a first word line signal and a second word line signal, respectively; and forming a third conductive feature and a fourth conductive feature configured to transmit a third word line signal and a fourth word line signal, respectively. A first memory cell, a second memory cell, a third memory cell and a fourth memory cell of the plurality of memory cells are configured to receive the third word line signal, the first word line signal, the second word line signal and the fourth word line signal, respectively. The third conductive feature and the fourth conductive feature are overlapped with the first conductive feature and the second conductive feature, respectively.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first memory cell configured to receive a first word line signal;
a second memory cell adjacent with the first memory cell, and configured to receive a second word line signal;
a first conductive feature crossing over each of the first memory cell and the second memory cell, and configured to transmit the first word line signal; and
a second conductive feature crossing over each of the first memory cell and the second memory cell, overlapped with the first conductive feature, and configured to transmit the second word line signal.

2. The device of claim 1, further comprising:
a third memory cell adjacent with the first memory cell, and configured to receive a third word line signal;
a fourth memory cell adjacent with the second memory cell, and configured to receive a fourth word line signal;
a third conductive feature crossing over each of the third memory cell and the fourth memory cell, and configured to transmit the fourth word line signal; and
a fourth conductive feature crossing over each of the third memory cell and the fourth memory cell, overlapped with the third conductive feature, and configured to transmit the third word line signal.

3. The device of claim 2, further comprising:
a fifth conductive feature disposed between the first conductive feature and the third conductive feature, and configured to transmit the first word line signal.

4. The device of claim 3, further comprising:
a sixth conductive feature disposed between the first conductive feature and the third conductive feature, separated from the fifth conductive feature, and configured to transmit the fourth word line signal.

5. The device of claim 3, further comprising:
a sixth conductive feature crossing over each of the second conductive feature and the fifth conductive feature, and configured to transmit the first word line signal.

6. The device of claim 1, further comprising:
a source/drain structure;
a first gate structure crossing over the source/drain structure; and
a first via structure configured to transmit the first word line signal to the first gate structure, and disposed directly above the source/drain structure.

7. The device of claim 6, further comprising:
a cut region configured to cut the first gate structure; and
a second via structure configured to transmit a reference voltage signal to the source/drain structure, and disposed directly above the cut region.

8. The device of claim 7, further comprising:
a third conductive feature crossing over the first gate structure, and configured to transmit the first word line signal;
a fourth conductive feature configured to transmit the reference voltage signal from the second via structure to the source/drain structure; and
a fifth conductive feature separated from the third conductive feature, crossing over the fourth conductive feature, and configured to transmit the reference voltage signal.

9. A device, comprising:
a first source/drain structure;
a second source/drain structure separated from the first source/drain structure along a first direction;
a first gate structure crossing over each of the first source/drain structure and the second source/drain structure;
a first via structure configured to transmit a first word line signal to the first gate structure;
a second via structure configured to transmit a reference voltage signal to the first source/drain structure; and
a third via structure configured to transmit the reference voltage signal to the second source/drain structure,
wherein the first via structure is disposed between the second via structure and the third via structure along the first direction.

10. The device of claim 9, further comprising:
a first conductive feature configured to transmit the first word line signal to the first via structure; and
a second conductive feature configured to transmit the reference voltage signal to the second source/drain structure, and separated from the second conductive feature along the first direction.

11. The device of claim 9, further comprising:
a third source/drain structure disposed between the first source/drain structure and the second source/drain structure; and
a first conductive feature and a second conductive feature aligned with and separated from each other, and each configured to transmit a bit line signal to the third source/drain structure.

12. The device of claim 9, further comprising:
a first conductive feature and a second conductive feature aligned with and separated from each other along the first direction, and configured to transmit the first word line signal and a second word line signal, respectively.

13. The device of claim 12, further comprising:
a third conductive feature and a fourth conductive feature configured to transmit a first bit line signal,
wherein the first conductive feature is disposed between the third conductive feature and the fourth conductive feature.

14. The device of claim 13, further comprising:
a fifth conductive feature configured to transmit the reference voltage signal and disposed between the third conductive feature and the first conductive feature.

15. The device of claim 14, further comprising:
a sixth conductive feature crossing over and configured to transmit the first bit line signal to each of the third conductive feature and the fourth conductive feature.

16. The device of claim 15, further comprising:
a seventh conductive feature crossing over and configured to transmit the reference voltage signal to the fifth conductive feature.

17. The device of claim 16, further comprising:
an eighth conductive feature crossing over and configured to transmit the first word line signal to the first conductive feature,
wherein the eighth conductive feature is disposed between the sixth conductive feature and the seventh conductive feature along the first direction.

18. A method, comprising:
forming a plurality of memory cells;
forming a first conductive feature and a second conductive feature configured to transmit a first word line signal and a second word line signal, respectively; and
forming a third conductive feature and a fourth conductive feature configured to transmit a third word line signal and a fourth word line signal, respectively,
wherein a first memory cell, a second memory cell, a third memory cell and a fourth memory cell of the plurality of memory cells are configured to receive the third word line signal, the first word line signal, the second word line signal and the fourth word line signal, respectively, and
the third conductive feature and the fourth conductive feature are overlapped with the first conductive feature and the second conductive feature, respectively.

19. The method of claim 18, further comprising:
forming a fifth conductive feature and a sixth conductive feature between the first conductive feature and the second conductive feature,
wherein the fifth conductive feature and the sixth conductive feature are aligned with and separated from each other, and are configured to transmit the third word line signal and the fourth word line signal, respectively.

20. The method of claim 19, further comprising:
forming a seventh conductive feature crossing over the fifth conductive feature and configured to transmit the third word line signal; and
forming an eighth conductive feature crossing over the sixth conductive feature and configured to transmit the fourth word line signal,
wherein the third conductive feature and the fourth conductive feature cross over the seventh conductive feature and the eighth conductive feature, respectively.
